(19) United States
(12) Patent Application Publication
(10) Pub. No.: US 2025/0120108 A1
(43) Pub. Date: Apr. 10, 2025

(54) METHOD FOR MANUFACTURING GATE-ALL-AROUND NANOSHEET STRUCTURE

(71) Applicant: INSTITUTE OF MICROELECTRONICS, CHINESE ACADEMY OF SCIENCES, Beijing (CN)

(72) Inventors: Na ZHOU, Beijing (CN); Junjie LI, Beijing (CN); Jianfeng GAO, Beijing (CN); Tao YANG, Beijing (CN); Junfeng LI, Beijing (CN); Jun LUO, Beijing (CN)

(21) Appl. No.: 18/725,965

(22) PCT Filed: Nov. 27, 2023
(86) PCT No.: PCT/CN2023/134257

§ 371 Date: Jul. 1, 2024

(30) Foreign Application Priority Data
Nov. 30, 2022 (CN) 202211533951.6

(51) Int. Cl. H10D 30/01; H10D 30/00; H10D 30/67; H10D 62/10; H10D 64/01

(52) U.S. Cl. CPC H10D 30/0191; H10D 30/014; H10D 30/502; H10D 30/6735; H10D 62/121; H10D 64/017

(57) ABSTRACT

A method for fabricating a GAA nanosheet structure, comprising: forming at least two channel layers and at least one sacrificial layer alternately stacked on a substrate to form a channel stack; forming, on the substrate, a dummy gate astride the channel stack; forming a first sidewall on a surface of the dummy gate; etching the sacrificial layer to form a recess at a side surface of the channel stack; forming a second sidewall within the recess; forming a source and a drain at two sides of the channel stack; in response to a channel layer being in contact with the dummy gate, etching the dummy gate and the channel layer to expose the at least one sacrificial layer, and then etching the at least one sacrificial layer to form a space for manufacturing a surrounding gate; and forming a metallic surrounding gate in the space.

This application claims priority to Chinese Patent Application No. 202211533951.6, titled “METHOD FOR ELIMINATING DAMAGE ON CHANNEL OF GATE-ALL-AROUND NANOSHEET”, filed on Nov. 30, 2022 with the China National Intellectual Property Administration, which is incorporated herein by reference in its entirety.

### FIELD

The present disclosure relates to the technical field of semiconductor device manufacturing, and in particular to a method for eliminating damages on a channel of a gate-all-around nanosheet.

### BACKGROUND

During manufacture of a gate-all-around (GAA) structure, a topmost layer of nanosheets is usually physically damaged in processes such as dummy-gate etching and ion implantation. Thereby, an effective current in a corresponding gate-all-around device would be reduced. Moreover, in GAA techniques, the topmost layer of nanosheets is apt to wrap and deform at its edge when a gate length is greater than 150 nm. Additionally, channel layer(s) and sacrificial layer(s) have different oxidation characteristics, and some elements in the sacrificial layer(s) are apt to diffuse at high temperature. Hence, when forming shallow trench isolation through high-density plasma deposition in a subsequent process, high-temperature oxidation would results in severe diffusion at edge(s) of fin(s), and the channel layer(s) and the sacrificial layer(s) would have irregular shapes, which induce concave corners among the fins and thus complicate subsequent processes During the high-density plasma deposition, the oxidation would further concentrate strain in the channel layer(s) at a bottom of the fin(s), and the strain may cause lattice defects in the topmost layer of nanosheets. Thereby, electrical performances of the final gate-all-around device would be reduced.

### SUMMARY

The method for eliminating damage on a channel of a gate-all-around (GAA) nanosheet is provided according to embodiments of the present disclosure. The damage on the channel of the nanosheet in gate-all-around devices can be effectively eliminated, and performances of the devices are improved.

A method for eliminating damage on a channel of a gate-all-around nanosheet is provided according to an embodiment of the present disclosure. The method comprises: forming at least two channel layers and at least one sacrificial layer, which are alternately stacked, sequentially on a substrate to form a channel stack: forming, on the substrate, a dummy gate astride the channel stack: forming a first sidewall on a surface of the dummy gate: etching the at least one sacrificial layer to form a recess at a side surface of the channel stack: forming a second sidewall within the recess: forming a source and a drain at two sides, respectively, of the channel stack: in response to a channel layer of the at least two channel layers being in contact with the dummy gate, etching the dummy gate and the channel layer to expose the at least one sacrificial layer, and then etching the at least one sacrificial layer to form a space for manufacturing a surrounding gate: and forming a metallic surrounding gate in the space to form a gate-all-around device.

In an embodiment, etching the dummy gate and the channel layer to expose the at least one sacrificial layer comprises: etching the dummy gate and then etching the channel layer: forming a first dielectric film which is made of a same material as the second sidewall: and etching the first dielectric film at a region corresponding to the at least one sacrificial layer, where the first dielectric film at a region above the second sidewall is retained.

In an embodiment, etching the sacrificial layer to form the space for manufacturing the surrounding gate comprises: performing chemical etching or atomic layer etching on the sacrificial layer to remove the sacrificial layer and form the space.

In an embodiment, forming the at least two channel layers and the at least one sacrificial layer, which are alternately stacked, sequentially on the substrate to form the channel stack comprises: growing at least two silicon films and at least one silicon germanium film, which are alternately stacked, sequentially on a silicon on insulator (SOI) substrate through epitaxy, where the at least one silicon germanium film serves as the at least one sacrificial layer, and the at least two silicon layers serve as the at least two channel layer: and performing dry etching on the channel stack to shape the channel stack into a fin extending along a first direction.

In an embodiment, forming, on the substrate, a dummy gate astride the channel stack comprises: forming a second dielectric film on a surface of the substrate and on the channel stack; and etching the second dielectric film based on a pattern of the channel stack to form the dummy gate, where the dummy gate and the channel stack form a stepped structure along the first direction, and the dummy gate extends across the channel stack along a second direction.

In an embodiment, forming the first sidewall on the surface of the dummy gate comprises: forming a third dielectric film on a surface of the dummy gate, a surface of the channel stack, and the surface of the substrate, where etching selectivity between the third dielectric film and the second dielectric film is not equal to 1: and etching the third dielectric film to form the first sidewall, where a surface of the first side wall and the side surface of the channel stack are aligned with a same position along the first direction, and the first sidewall covers side surfaces of the dummy gate and a top surface of the dummy gate.

In an embodiment, etching the at least one sacrificial layer to form the recess at the ide surface of the channel stack comprises: etching each sacrificial layer of the at least one sacrificial layer from a side wall of said sacrificial layer to form the recess, where a depth of the recess is identical to a thickness of the first sidewall.

In an embodiment, forming the second sidewall within the recess comprises: forming a first dielectric film, where a thickness of the first dielectric film is more than or equal to a depth of the recess: and etching the first dielectric film to form the second sidewall, where a surface of the second sidewall and a side surface of the at least two channel layers are aligned with a same position along the first direction.

In an embodiment, before etching the dummy gate and the channel layer, the method further comprises: removing the third dielectric film at a top of the dummy gate through planarization to expose the top surface of the dummy gate.

In an embodiment, forming the metallic surrounding gate in the space comprises: forming the metallic surrounding gate in the space through atomic layer deposition or vapor deposition.

The technical solutions provided herein address an issue that defects are likely to be generated in a topmost layer of nanosheets when manufacturing gate-all-around devices. When the topmost nanosheet for a channel is directly adjacent to a bottom of the dummy gate, such nanosheet is also etched along with the dummy gate. The atomic layer etching having high selectivity may be preferable. Therefore, the nanosheet having defects is removed while good nanosheets are retailed, which ensures performances of the entire device.

### BRIEF DESCRIPTION OF THE DRAWINGS

FIG. 1 is a flow chart of a method for eliminating damage on a channel of a gate-all-around nanosheet according to an embodiment of the present disclosure.

FIG. 2 is a flow chart of a process of filling recesses formed through etching channel layers in a method for eliminating damage on a channel of a gate-all-around nanosheet according to an embodiment of the present disclosure.

FIG. 3 is a flow chart of a process of etching a channel stack in a method for eliminating damage on a channel of a gate-all-around nanosheet according to an embodiment of the present disclosure.

FIG. 4 is a flow chart of forming a dummy gate in a method for eliminating damage on a channel of a gate-all-around nanosheet according to an embodiment of the present disclosure.

FIG. 5 is a flow chart of forming a first sidewall in a method for eliminating damage on a channel of a gate-all-around nanosheet according to an embodiment of the present disclosure.

FIG. 6 is a flow chart of forming a second sidewall in a method for eliminating damage on a channel of a gate-all-around nanosheet according to an embodiment of the present disclosure.

FIG. 7 is a schematic structural diagram showing a structure after forming sacrificial layers and channel layers in a method for eliminating damage on a channel of a gate-all-around nanosheet according to an embodiment of the present disclosure.

FIG. 8 is a schematic structural diagram showing a channel stack formed in a method for eliminating damage on a channel of a gate-all-around nanosheet according to an embodiment of the present disclosure.

FIG. 9 is a schematic structural diagram showing a dummy gate and a first sidewall formed in a method for eliminating damage on a channel of a gate-all-around nanosheet according to an embodiment of the present disclosure.

FIG. 10 is a schematic structural diagram showing recesses formed in a method for eliminating damage on a channel of a gate-all-around nanosheet according to an embodiment of the present disclosure.

FIG. 11 is a schematic structural diagram showing second sidewalls formed in a method for eliminating damage on a channel of a gate-all-around nanosheet according to an embodiment of the present disclosure.

FIG. 12 is a schematic structural diagram showing a source and a drain formed in a method for eliminating damage on a channel of a gate-all-around nanosheet according to an embodiment of the present disclosure.

FIG. 13 is a schematic structural diagram showing a structure formed after etching a dummy gate in a method for eliminating damage on a channel of a gate-all-around nanosheet according to an embodiment of the present disclosure.

FIG. 14 is a schematic structural diagram showing a structure formed after etching a channel layer in a method for eliminating damage on a channel of a gate-all-around nanosheet according to an embodiment of the present disclosure.

FIG. 15 is a schematic structural diagram showing a structure formed after filling a recess formed through etching a channel layer in a method for eliminating damage on a channel of a gate-all-around nanosheet according to an embodiment of the present disclosure.

FIG. 16 is a schematic structural diagram showing a structure formed after etching a sacrificial layer in a method for eliminating damage on a channel of a gate-all-around nanosheet according to an embodiment of the present disclosure.

FIG. 17 is a schematic structural diagram showing a structure formed after forming a metal gate in a method for eliminating damage on a channel of a gate-all-around nanosheet according to an embodiment of the present disclosure.

FIG. 18 is a schematic structural diagram showing metal plugs formed in a method for eliminating damage on a channel of a gate-all-around nanosheet according to an embodiment of the present disclosure.

### DETAILED DESCRIPTION OF EMBODIMENTS

Hereinafter technical solutions in embodiments of the present disclosure are described clearly and completely in conjunction with the drawings in embodiments of the present closure, in order to clarify purposes, the technical solutions, and advantages of the present disclosure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

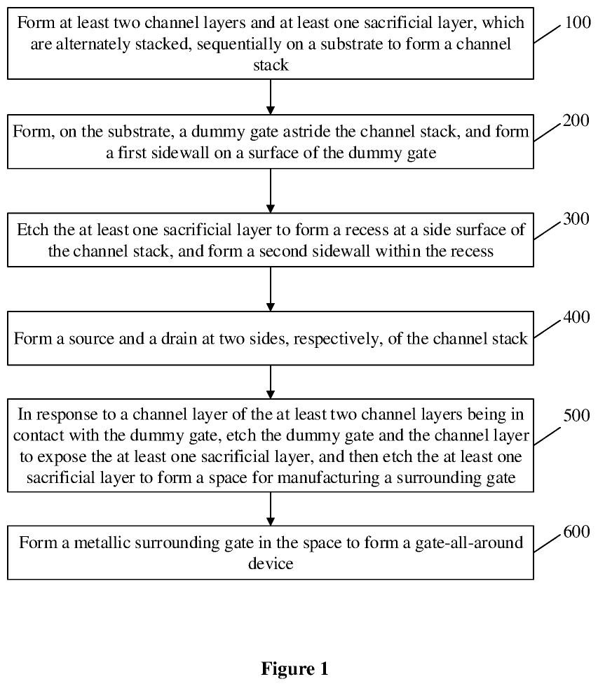

A method for eliminating damage on a channel of a gate-all-around nanosheet is provided according to an embodiment of the present disclosure. Reference is made to FIG. 1, where the method comprises following steps 100 to 600.

In step 100, at least two channel layers and at least one sacrificial layer, which are alternately stacked, are sequentially formed on a substrate, so as to form a channel stack.

In some embodiments, the substrate refers to a structure that supports a semiconductor device. In an embodiment, the substrate may be a silicon-on-insulator substrate, or other substrates. The channel layer refers to a material film serving as the channel in a final device. The sacrificial layer refers to a material film which would be removed when manufacturing the device. A layer which is first formed in this step may be either the channel layer or the sacrificial layer. The sacrificial layer may be made of silicon germanium, germanium, silicon carbide, or III-V gallium arsenide. The channel layer may be made of silicon, silicon germanium, germanium, silicon carbide, or III-V gallium arsenide, and its material is different from that of the sacrificial layer. That is, different types for material are selected for the channel layer(s) and the sacrificial layer(s), such that the channel layer(s) can be retained when removing the sacrificial layer(s).

In step 200, a dummy gate astride the channel stack is formed on the substrate, and a first sidewall is formed on a surface of the dummy gate.

In some embodiments, the dummy gate refers to a material film formed in a region corresponding to a gate. The material film serves as a placeholder which reserves a space for the gate. In subsequent steps, the dummy gate would be removed before fabricating the gate, such that the space is released for forming the gate. The dummy gate astride the channel stack may refer to that an extending direction of the dummy gate is perpendicular to an extending direction of the channel stack, and that the dummy gate extends to cover two opposite side surfaces and a top surface of the channel stack. Forming the first sidewall on the surface of the dummy gate refers to forming the first sidewall which wraps the dummy gate at least partially. That is, the first sidewall covers side surfaces and a top surface of the dummy gate.

In step 300, the at least one sacrificial layer is etched to form a recess at a side surface of the channel stack, and a second sidewall is formed within the recess.

In some embodiments, when etching the at least one sacrificial layer, each sacrificial layer is etched inward from its exposed sidewall. After the etching, a part of the at least one sacrificial layer is removed, and hence the recess is formed at the side surface of the channel stack at position(s) corresponding to the sacrificial layer(s). Forming the second sidewall refers to that the recess is filled to flatten the side surface of the channel stack again. A filling material may be one or a combination among SiC, Si₃N₄, and SiON. The space occupied by the at least one sacrificial layer is for subsequent fabrication of the surrounding gate, and hence the second sidewall has two functions. One function is limiting a dimension of the surrounding gate, and another function is insulating the surrounding gate from the source and drain.

In step 400, a source and a drain are formed at two sides, respectively, of the channel stack.

In some embodiments, the side surfaces of the at least two channel layers in the channel stack are exposed, and hence the channel layers would be in contact with the source and the drain when the source and the drain has been manufactured.

In step 500, in response to a channel layer of the at least two channel layers being in contact with the dummy gate, the dummy gate and the channel layer etched to expose the at least one sacrificial layer is exposed, and then the at least one sacrificial layer are etched to form a space for manufacturing a surrounding gate.

In some embodiments, the topmost channel layer in the channel stack is in contact with the dummy gate, and hence a topmost nanosheet for a channel may be damaged due to etching, ion implantation, and/or high-temperature oxidation. In order to guarantee performances of the device, after the dummy gate has been etched, such channel layer is exposed and then removed through etching until the topmost sacrificial layer is exposed. The at least sacrificial layer is exposed when the dummy gate and the topmost channel layer have been removed, and then the at least one sacrificial layer is etched. After the at least one sacrificial layer has been removed, the space occupied by the at least one sacrificial layer is vacant. When manufacturing the channel stack, an alternative case is that the topmost sacrificial layer in the channel stack is in contact with the dummy gate. In such case, the topmost sacrificial layer is capable to protect the topmost channel layer, and hence it is not necessary to remove the topmost channel layer through additional etching. That is, the at least one sacrificial layer is directly etched after the dummy gate has been removed.

In step 600, a metallic surrounding gate is formed in the space, so as to form a gate-all-around device.

In some embodiments, the space occupied by the at least one sacrificial layer and the dummy gate is vacant after they have been removed, and such space may be utilized for fabricating the surrounding gate. Such space surrounds the channel layer(s) because the dummy gate and the at least one sacrificial layer constitute a structure wrapping the at least two channel layers. A dielectric-metal gate structure may be formed in the space to surround the channel layer(s). In some embodiments, a dielectric layer in the gate structure may be made of a high-κ dielectric material.

The technical solutions provided herein address an issue that defects are likely to be generated in a topmost layer of nanosheets when manufacturing gate-all-around devices. When the topmost nanosheet for the channel is directly adjacent to a bottom of the dummy gate, such nanosheet is also etched along with the dummy gate. Therefore, the nanosheet having defects is removed while good nanosheets are retailed, which ensures performances of the entire device.

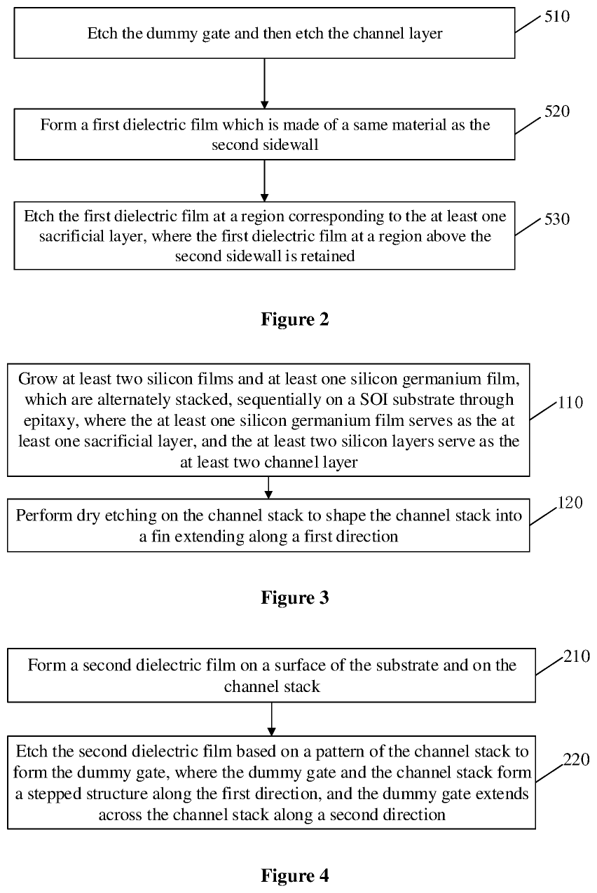

Reference is made to FIG. 2. In an embodiment, etching the dummy gate and the channel layer to expose the at least one sacrificial layer comprises following steps 510 to 530.

In step 510, the dummy gate is etched, and then the channel layer is etched.

In some embodiments, the dummy gate and the channel layer are made of different materials, and hence they need to be etched differently through two-step etching. The dummy gate is etched first to expose the channel layer, and then the exposed channel layer is etched.

In step 520, a first dielectric film, which is made of a same material as the second sidewall, is formed.

In some embodiments, a cavity is formed under the first sidewall after the channel layer has been etched, and usually a small portion of the channel layer remains. Although the remaining portion may be capable to insulate the surrounding gate from the source and the drain in subsequent steps, a dimension of the remaining portion is difficult to control. The remaining portion may be such little that a short circuit is induced. In order to address such issue, a layer having the same material as the second sidewall is utilized to form the first dielectric film. The first dielectric film fills at least a space which is located above the second sidewall after the channel layer has been etched.

In step 530, the first dielectric film is etched at a region corresponding to the at least one sacrificial layer, where the first dielectric film at a region above the second sidewall is retained.

In some embodiments, the first dielectric film covers a surface of the entire current structure after being formed, and thus it needs to be etched. The first dielectric film at the region corresponding to the second sidewall is retained after such etching.

In an embodiment, etching the sacrificial layer to form the space for manufacturing the surrounding gate comprises a following step. Chemical etching or atomic layer etching is performed on the sacrificial layer to remove the sacrificial layer and form the space.

Herein the sacrificial layer(s) are located in a space surrounding the channel layer(s), and a portion of the sacrificial layer(s) is occluded. Thus, the chemical etching or the atomic layer etching may be performed to etch the sacrificial layer successfully.

Reference is made to FIG. 3. In an embodiment, forming the at least two channel layers and the at least one sacrificial layer, which are alternately stacked, sequentially on the substrate to form the channel stack comprises following steps 110 and 120.

In step 110, at least two silicon films and at least one silicon germanium film, which are alternately stacked, are sequentially grown on a silicon on insulator (SOI) substrate through epitaxy, where the at least one silicon germanium film serves as the at least one sacrificial layer, and the at least two silicon layers serve as the at least two channel layer.

In some embodiments, the silicon film may serve as the channel layer due to its characteristics suitable for a channel layer, and the silicon germanium film may serve as the sacrificial layer because its etching selectivity with respect to the silicon film facilitates retaining the silicon film when it is being etched.

In step 120, dry etching is performed on the channel stack to shape the channel stack into a fin extending along a first direction.

In some embodiments, a channel stack is formed on the entire surface of the substrate in the epitaxial growth. Hence, in order to manufacture the device, the channel stack needs to be shaped into fin(s) which facilitates forming the dummy gate astride the channel stack.

Reference is made to FIG. 4. In an embodiment, forming, on the substrate, a dummy gate astride the channel stack comprises following steps 210 to 220.

In step 210, a second dielectric film is formed on a surface of the substrate and on the channel stack.

In some embodiments, the formed second dielectric film covers the substrate and the channel stack and has a conformed structure extending from the surface of the substrate surface to the surface of channel stack surface. That is, a sidewall of the channel stack is covered by the second dielectric film.

In step 220, the second dielectric film is etched based on a pattern of the channel stack to form the dummy gate, where the dummy gate and the channel stack form a stepped structure along the first direction, and the dummy gate extends across the channel stack along a second direction.

In some embodiments, after the second dielectric film has been etched, a dimension of the remaining second dielectric film in the first direction is a dimension of the channel stack in the first direction. That is, the stepped structure is formed by the second dielectric film and the channel stack. At the same time, a dimension of the remaining second dielectric film in the second direction is larger than a dimension of the channel stack in the second direction. That is, the dummy gate extends across the channel stack. A central axis of the dummy gate and a central axis of the channel stack may be aligned with a same position along the first direction. A central axis of the dummy gate and a central axis of the channel stack may be aligned with a same position along the second direction.

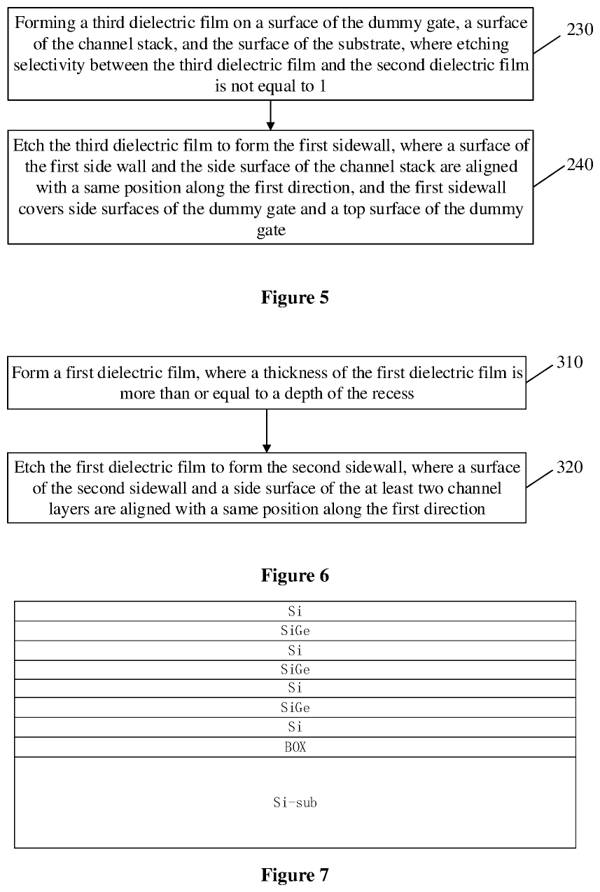

Reference is made to FIG. 5. In an embodiment, forming the first sidewall on the surface of the dummy gate comprises following steps 230 to 240.

In step 230, a third dielectric film is formed on a surface of the dummy gate, a surface of the channel stack, and the surface of the substrate, where etching selectivity between the third dielectric film and the second dielectric film is not equal to 1.

In some embodiments, the formed third dielectric film has a conformal structure covering the surface of the dummy gate, the surface of the channel stack, and the surface of the substrate. Thereby, side surfaces of the dummy gate and the side surface of the channel stack are covered. The third dielectric film and the second dielectric film have etching selectivity not equal to 1, and hence the third dielectric film, i.e., the first sidewall, would not be damaged when etching the dummy gate, which facilitates forming the surrounding gate in subsequent steps.

In step 240, the third dielectric film is etched to form the first sidewall, where a surface of the first side wall and the side surface of the channel stack are aligned with a same position along the first direction, and the first sidewall covers side surfaces of the dummy gate and a top surface of the dummy gate.

In some embodiments, after being etched, a side surface of a remaining portion of the third dielectric film and the side surface of the channel stack are aligned with the same position in the first direction. Thereby, the side surface of the channel stack is exposed, such that the recess can be formed in the subsequent step of etching the at least one sacrificial layer. Since the dimension of the dummy gate in the first direction is smaller than the dimension of the channel stack in the first direction, the remaining portion on the two side surfaces of the dummy gate along a direction perpendicular to the first direction have a sufficient thickness.

In an embodiment, etching the at least one sacrificial layer to form the recess at the ide surface of the channel stack comprises a following step. Each sacrificial layer is etched from a side wall of such sacrificial layer to form the recess, where a depth of the recess is identical to a thickness of the first sidewall.

Herein the surrounding gate occupies the space once occupied by the dummy gate and the at least one sacrificial layer when being formed. Thus, an etching depth being equal to the thickness of the first sidewall facilitates forming the surrounding gate having a uniform dimension along the first direction.

Reference is made to FIG. 6. In an embodiment, forming the second sidewall within the recess comprises following steps 310 and 320.

In step 310, a first dielectric film is formed, where a thickness of the first dielectric film is more than or equal to a depth of the recess.

In some embodiments, the formed first dielectric film has a conformal structure covering a top surface of each component, i.e., covering a surface of the entire current structure. In order to fill the recess fully, the thickness of the first dielectric film is configured to be more than or equal to the depth of the recess.

In step 320, the first dielectric film is etched to form the second sidewall, where a surface of the second sidewall and a side surface of the at least two channel layers are aligned with a same position along the first direction.

In some embodiments, all the first dielectric film located outside the recess may be removed when etching the first dielectric film. That is, only a portion of the first dielectric film located inside the recess is retained as the second sidewall.

In an embodiment, before etching the dummy gate and the channel layer, the method further comprises a following step. The third dielectric film at a top of the dummy gate is removed through planarization to expose the top surface of the dummy gate.

Herein the third dielectric film covers the top surface of the dummy gate when being formed, and at least a portion of the third dielectric film on the top surface of the dummy gate may remain after the third dielectric film has been etched. Hence, such portion of the third dielectric film needs to be planarized before etching the dummy gate, and the dummy gate may be not etched until being exposed.

In an embodiment, forming the metallic surrounding gate in the space comprises a following step. The metallic surrounding gate is formed in the space through atomic layer deposition or vapor deposition.

Herein the space for manufacturing the surrounding gate surrounds the channel layer(s) and has a special shape. In order to fabricate a gate structure having metal and a high-K dielectric material in such space, the atomic layer deposition or the vapor deposition may be utilized.

Reference is made to FIGS. 7 to 18, which provide an example for illustrating a technical solution according to an embodiment of the present disclosure.

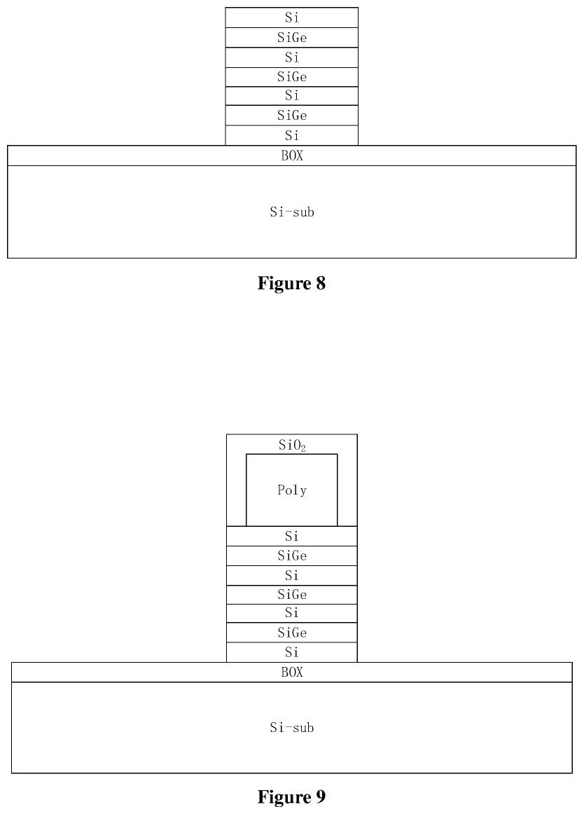

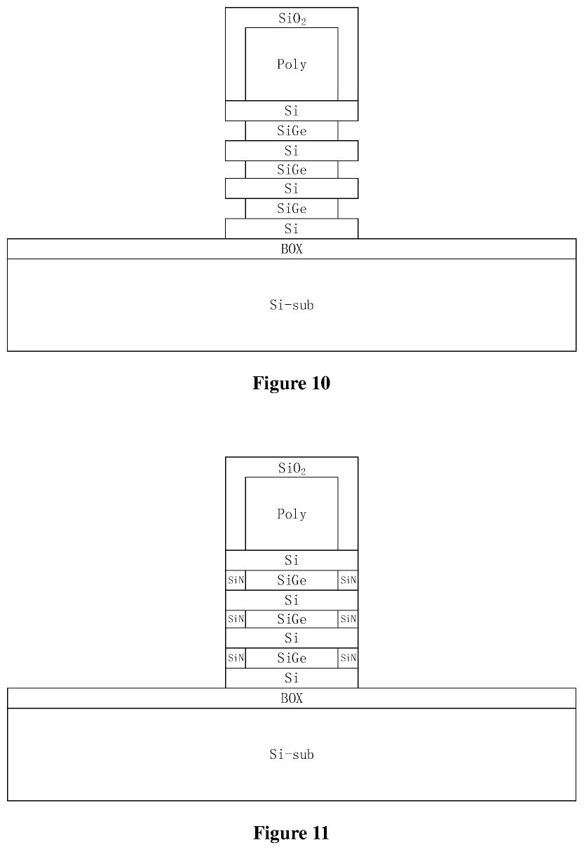

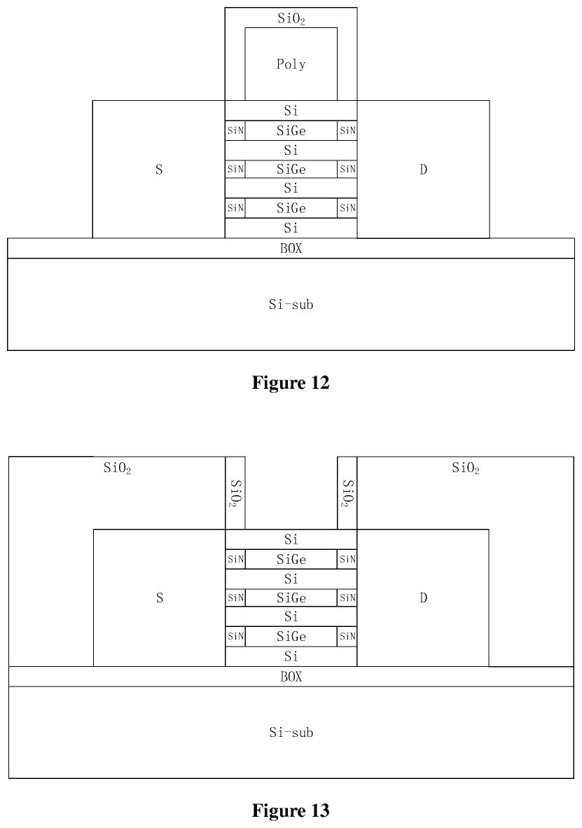

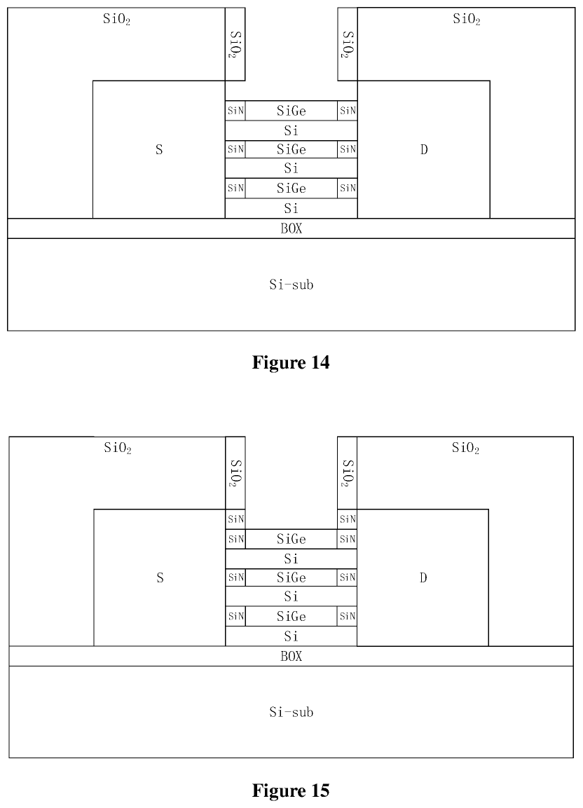

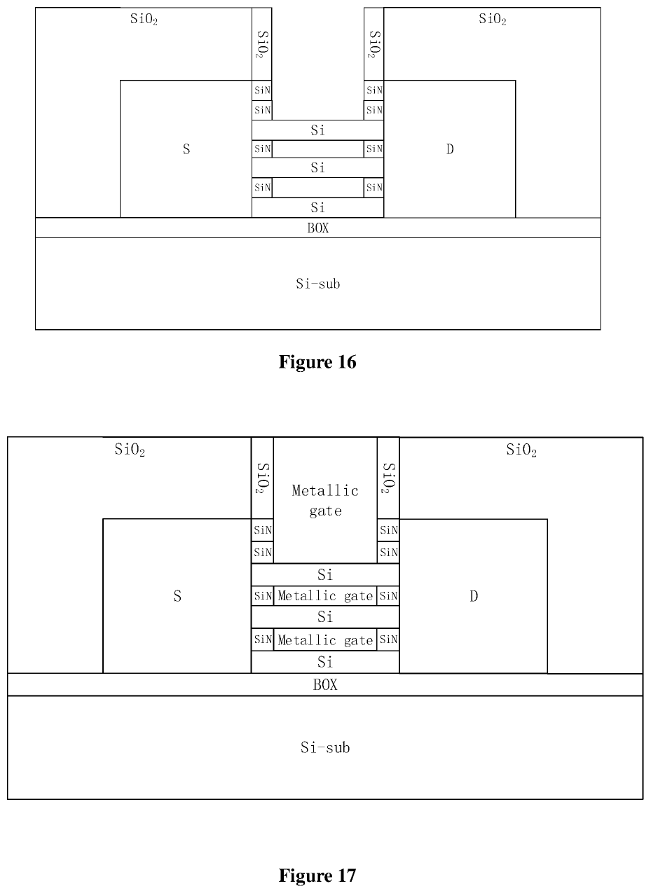

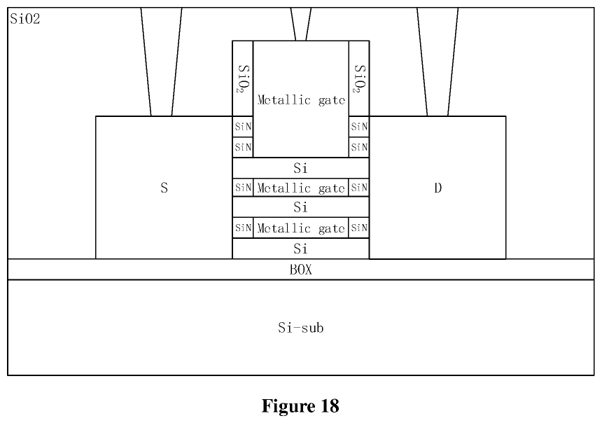

First, SiGe layers and Si layers are sequentially grown on a silicon on insulator (SOI) wafer through epitaxy. A quantity of nanowires formed in subsequent steps depends on the Si layers. At least on channel layer needs to be retained in the final device, while the topmost channel layer needs to be removed. Hence, a quantity of the Si layers is at least two. In this embodiment, the SiGe layers serve as the sacrificial layers, and the Si layers serve as channel layers. The stacked layers that are formed may be as shown in FIG. 7. The stacked layers need to be photolithographed and etched, so as to shape the stacked layers as a requirement of the device. As an example, the etching is dry etching. The channel stack formed after the etching may be as shown in FIG. 8. A film such as a polysilicon film is deposited and then etched to form the dummy gate. Another film such as a silicon dioxide film is deposited and then etched to form the first sidewall. The structure obtained after forming the first sidewall may be as shown in FIG. 9. After forming the first sidewall, the sacrificial layer is etched to form the recesses, as shown in FIG. 10. After forming the recesses, a film as a silicon nitride film is deposited and then etched to form the second sidewalls. A structure obtained after forming the second sidewall may be shown in FIG. 11. When forming the second sidewall, the etching may be anisotropic etching with high selectivity, such that the film is quickly removed along a horizontal direction while slowly removed along a vertical direction. After the second sidewalls have been formed, the source and the drain are formed in source-drain regions through epitaxial growth. A structure obtained after forming the source and the drain may be as shown in FIG. 12. After the source and the drain have been formed, the structure is planarized through, for example, chemical mechanical polishing to remove the silicon dioxide film on the top surface of the dummy gate. Then, the dummy gate is removed through etching, e.g., through wet etching. A structure obtained after removing the dummy gate may be as shown in FIG. 13. After the dummy gate has been removed, the channel layer needs to be removed through etching when it was previously in contact with the dummy gate. For example, the topmost channel layer is removed through atomic layer etching. A structure obtained after removing the topmost channel layer may be as shown in FIG. 14. After the dummy gate and the topmost channel layer have been removed, a new dielectric film is formed on the device, so as to avoid that the source and the drain are exposed after the removing the channel layer and thus a short circuit is introduced when forming the surrounding gate subsequently. For example, a silicon nitride film or a silicon nitride oxide film may be formed through atomic layer deposition. After being formed, the new dielectric film is subject to anisotropic etching, such that its portion outside the region corresponding to the second sidewalls is removed. A structure obtained after the above processing may be as shown in FIG. 15. Afterwards, the sacrificial layers are exposed and thus can be etched. The etching may be dry etching, wet atomic layer etching, or reaction etching through a hydrogen-chloride gas. After the sacrificial layers have been etched, the space once occupied by the dummy gate and the sacrificial layers are vacant, as shown in FIG. 16. Then, a metal gate along with a high-k dielectric material is fabricated in the space, that is, the metallic surrounding gate is formed. A structure obtained after the above processing may be as shown in FIG. 17. Afterwards, a dielectric film such as a silicon dioxide film is formed, and metal plugs are formed in holes opened in the dielectric film. Thereby, the final device is formed. A structure of the final device may be as shown in FIG. 18.

Hereinabove described are only embodiments of the present disclosure, and the protection scope of the present disclosure is not limited to these embodiments. Any modification or substitution that can be easily obtained by those skilled in the art within a technical scope disclosed herein shall fall within a protection scope of the present disclosure. Therefore, the protection scope of the present disclosure is subject to a scope of the claims.

1. A method for manufacturing a gate-all-around nanosheet structure, comprising:
forming at least two channel layers and at least one sacrificial layer, which are alternately stacked, sequentially on a substrate to form a channel stack;
forming, on the substrate, a dummy gate astride the channel stack;
forming a first sidewall on a surface of the dummy gate;
etching the at least one sacrificial layer to form a recess at a side surface of the channel stack;
forming a second sidewall within the recess;
forming a source and a drain at two sides, respectively, of the channel stack;
in response to a channel layer of the at least two channel layers being in contact with the dummy gate, etching the dummy gate and the channel layer to expose the at least one sacrificial layer, and then etching the at least one sacrificial layer to form a space for manufacturing a surrounding gate; and
forming a surrounding gate structure comprising metal and a dielectric layer in the space to form the gate-all-around nanosheet structure.

2. The method according to claim 1, wherein etching the dummy gate and the channel layer to expose the at least one sacrificial layer comprises:
removing the dummy gate and the channel layer through etching;
forming a first dielectric film at least at a position of the removed channel layer, wherein the first electric film is made of a same material as the second sidewall; and
etching the first dielectric film at a region above the at least one sacrificial layer, wherein the first dielectric film at a region above the second sidewall is retained.

3. The method according to claim 1, wherein etching the sacrificial layer to form the space for manufacturing the surrounding gate comprises:
performing chemical etching or atomic layer etching on the sacrificial layer.

4. The method according to claim 1, wherein forming the at least two channel layers and the at least one sacrificial layer, which are alternately stacked, sequentially on the substrate to form the channel stack comprises:
growing at least two silicon films and at least one silicon germanium film, which are alternately stacked, sequentially on a silicon on insulator (SOI) substrate through epitaxy, wherein the at least one silicon germanium film serves as the at least one sacrificial layer, and the at least two silicon layers serve as the at least two channel layer; and
performing dry etching on the channel stack to shape the channel stack into a fin extending along a first direction.

5. The method according to claim 1, wherein forming, on the substrate, a dummy gate astride the channel stack comprises:
forming a second dielectric film on a surface of the substrate and on the channel stack; and
etching the second dielectric film to form the dummy gate, wherein the dummy gate and the channel stack form a stepped structure along the first direction, and the dummy gate extends across the channel stack along a second direction.

6. The method according to claim 5, wherein forming the first sidewall on the surface of the dummy gate comprises:
forming a third dielectric film on a surface of the dummy gate, a surface of the channel stack, and the surface of the substrate, wherein etching selectivity between the third dielectric film and the second dielectric film is not equal to 1; and
etching the third dielectric film to form the first sidewall, wherein a surface of the first side wall and the side surface of the channel stack are aligned with a same position along the first direction, and the first sidewall covers side surfaces of the dummy gate and a top surface of the dummy gate.

7. The method according to claim 1, wherein etching the at least one sacrificial layer to form the recess at the ide surface of the channel stack comprises:
etching each sacrificial layer of the at least one sacrificial layer from a side wall of said sacrificial layer to form the recess, wherein a depth of the recess is identical to a thickness of the first sidewall.

8. The method according to claim 1, wherein forming the second sidewall within the recess comprises:
forming a first dielectric film at the side surface of the channel stack, wherein a thickness of the first dielectric film is more than or equal to a depth of the recess; and
etching the first dielectric film to form the second sidewall, wherein a surface of the second sidewall and a side surface of the at least two channel layers are aligned with a same position along the first direction.

9. The method according to claim 6, wherein before etching the dummy gate and the channel layer, the method further comprises:
removing the third dielectric film at a top of the dummy gate through planarization to expose the top surface of the dummy gate.

10. The method according to claim 1, wherein forming the metallic surrounding gate in the space comprises:
forming the metallic surrounding gate in the space through atomic layer deposition or vapor deposition.
